(19) United States
(12) Patent Application Publication
(10) Pub. No.: US 2011/0120375 A1
(43) Pub. Date: May 26, 2011

(54) APPARATUS FOR PROCESSING SUBSTRATE

(75) Inventors: Myung-Gon SONG, Jeollanam-do (KR); Jung-Rak Lee, Gyeonggi-do (KR); Jae-Chul Do, Daegu (KR); Bu-Il Jeon, Gyeonggi-do (KR)

(73) Assignee: JUSUNG ENGINEERING CO., LTD., Gyeonggi-do (KR)

(21) Appl. No.: 12/950,928

(22) Filed: Nov. 19, 2010

(30) Foreign Application Priority Data
Nov. 23, 2009 (KR) 10-2009-0113254
Nov. 23, 2009 (KR) 10-2009-0113257

(51) Int. Cl. C23C 16/453

(52) U.S. Cl. 118/723 E; 118/723 R

(57) ABSTRACT

An apparatus for processing a substrate includes: a process chamber providing a reaction space by a combination of a lid and a body; a susceptor in the reaction space and having a substrate thereon; a plurality of plasma source electrodes over the reaction space; a plurality of first lower protruding portions under the lid; and a plurality of first gas injecting means corresponding to the plurality of plasma source electrodes and a plurality of second gas injecting means alternately disposed with the plurality of first gas injecting means.

### CROSS-REFERENCE TO RELATED APPLICATION

This application claims the benefit of Korean Patent Application No. 10-2009-0113254, filed on Nov. 23, 2009 and No. 10-2009-0113257, filed on Nov. 23, 2009, which are hereby incorporated by a reference in its entirety.

### BACKGROUND OF THE INVENTION

1. Technical Field

The present invention relates to an apparatus for processing a substrate, and more particularly, to an apparatus including a gas injecting means in a plasma source electrode and a plasma ground electrode.

2. Discussion of the Related Art

In general, a semiconductor device, a display device and a solar cell are fabricated through a depositing process where a thin film is formed on a substrate, a photolithographic process where a thin film is selectively exposed and shielded by a photosensitive material and an etching process where a thin film is selectively removed. Among the fabricating processes, the deposition process and the etching process are performed in a fabricating apparatus using a plasma in a chamber of an optimum vacuum state.

The fabricating apparatus may be classified into an inductively coupled plasma (ICP) type and a capacitively coupled plasma (CCP) type according to a method of generating the plasma. The ICP type may be used for a reactive ion etching (RIE) apparatus and a plasma enhanced chemical vapor deposition (PECVD) apparatus, and the CCP type may be used for a high density plasma (HDP) etching apparatus and a HDP deposition apparatus.

FIG. 1 is a CCP type apparatus for processing a substrate according to the related art. In FIG. 1, a CCP type apparatus 10 includes a process chamber 12 providing a reaction space, a rear plate 14 in the reaction chamber 12 and used as a plasma source electrode, a gas supplying pipe 36 supplying a process gas to the process chamber 12 and connected to the rear plate 14, a gas distributing plate 18 of aluminum (Al) under the rear plate 14 and having a plurality of injecting holes 16, a susceptor 22 used as a plasma ground electrode facing the plasma source electrode and having a substrate 20 thereon, a gate 40 for transferring the substrate 20 to and from the process chamber 12, and an exhaust 24 for outputting a reaction gas and a residual product from the process chamber 12.

The gas supplying pipe 36 is connected to a radio frequency (RF) power supply 30 through a feeding line 38. A matcher 32 for matching an impedance is disposed between the RF power supply 30 and the feeding line 38. The susceptor 22 and the process chamber 12 are grounded. The gas distributing plate 18 includes a buffer space 26 with the rear plate 14 and is supported by a supporting means 28 extending from and connected to the rear plate 14.

When an RF power of the RF power supply 30 is applied to a central portion of the rear plate 14, an RF electromagnetic field is generated between the rear plate 14 and the susceptor 22. The process gas is ionized or activated by the RF electromagnetic field, and a depositing process or an etching process for the substrate 20 is performed.

When the gas distributing plate 18 electrically connected to the rear plate 14 is used, the process gas is uniformly supplied to a portion over the susceptor 22 by the gate distributing plate 18. In addition, when an RF power having a relatively short wavelength is used to improve the efficiency of plasma generation, the plasma source electrode may be divided into a plurality of electrodes to overcome a standing wave effect.

However, when the plasma source electrode connected to the RF power supply 30 is divided into the plurality of electrodes, the gas distributing plate 18 connected to the rear plate 14 cannot be formed in the process chamber 12. Accordingly, when the plasma source electrode includes the plurality of electrodes, a gas injecting means is required to supply the process gas to the reaction space uniformly.

FIG. 2 is an ICP type apparatus for processing a substrate according to the related art. In FIG. 2, an IC type apparatus 50 includes a process chamber 52 including a lid 52a and a body 52b and providing a reaction space, a gas supplying pipe 56 supplying a process gas to the reaction space, a susceptor 60 in the reaction space and having a substrate 58 thereon, and an exhaust 62 for outputting a reaction gas and a residual product from the process chamber 52. An antenna 54 is connected to a radio frequency (RF) power supply 64 supplying an RF power, and a matcher 66 for matching an impedance is disposed between the antenna 54 and the RF power supply 64.

The antenna 54 having a coil shape is disposed over the lid 52a, and the RF power is applied to the antenna 54 to generate an induced electric field around the antenna 54. A surface of the antenna 54 is alternately charged with a positive electricity and a negative electricity by the RF power to generate an induced magnetic field. The lid 52a under the antenna 54 is formed of dielectric material so that the induced magnetic field from the antenna 54 can penetrate into the process chamber 52 of a vacuum state.

The gas supplying pipe 56 is formed through a central portion of the lid 52a, and the process gas is supplied to the reaction space through the gas supplying pipe 56. When the RF power is applied to the antenna 54, the process gas through the gas supplying pipe 56 is ionized or activated, and a depositing process or an etching process for the substrate 58 is performed.

However, since the process gas is supplied to the central portion of the lid 52a by the gas supplying pipe 56, a density of the process gas in a peripheral portion of the reaction space is smaller than a density of the process gas in the central portion of the reaction space. Accordingly, a plasma density in the peripheral portion of the reaction space is smaller than a plasma density in the central portion of the reaction space, and the substrate 58 is seldom processed uniformly.

### SUMMARY OF THE INVENTION

Accordingly, the present invention is directed to an apparatus for processing a substrate that substantially obviates one or more of the problems due to limitations and disadvantages of the related art.

An object of the present invention is to provide a CCP type apparatus for processing a substrate where a standing wave effect is prevented by a plurality of plasma source electrodes and a process gas is uniformly supplied to a reaction space by a gas injecting means including a first gas injecting means in each of the plurality of plasma source electrodes and a second gas injecting means in each of a plurality of protruding portions.

Another object of the present invention is to provide an ICP type apparatus for processing a substrate where a process gas is uniformly supplied to a reaction space by a gas injecting means including a first gas injecting means in each of a plurality of first protruding portions corresponding to an antenna as a plasma source electrode and a second gas injecting means in each of a plurality of second protruding portions as a plasma ground electrode.

To achieve these and other advantages and in accordance with the purpose of the present invention, as embodied and broadly described, an apparatus for processing a substrate includes: a process chamber providing a reaction space by a combination of a lid and a body; a susceptor in the reaction space and having a substrate thereon; a plurality of plasma source electrodes over the reaction space; a plurality of first lower protruding portions under the lid; and a plurality of first gas injecting means corresponding to the plurality of plasma source electrodes and a plurality of second gas injecting means alternately disposed with the plurality of first gas injecting means.

It is to be understood that both the foregoing general description and the following detailed description are exemplary and explanatory and are intended to provide further explanation of the invention as claimed

### BRIEF DESCRIPTION OF THE DRAWINGS

The accompanying drawings, which are included to provide a further understanding of the invention and are incorporated in and constitute a part of this specification, illustrate embodiments of the invention.

In the drawings:

FIG. 1 is a CCP type apparatus for processing a substrate according to the related art;

FIG. 2 is an ICP type apparatus for processing a substrate according to the related art;

FIG. 3 is a cross-sectional view showing an apparatus for processing a substrate according to a first embodiment of the present invention;

FIG. 4 is a plan view showing a plurality of plasma source electrodes of an apparatus for processing a substrate according to a first embodiment of the present invention;

FIG. 5 is a perspective view showing a lid of an apparatus for processing a substrate according to a first embodiment of the present invention;

FIG. 6 is a magnified view of portion A of FIG. 3;

FIG. 7 is a perspective view showing a plurality of first gas injecting means of an apparatus for processing a substrate according to a first embodiment of the present invention;

FIG. 8 is a perspective view showing a plurality of second gas injecting means of an apparatus for processing a substrate according to a first embodiment of the present invention

FIG. 9 is a cross-sectional view taken along a line IX-IX of FIG. 5;

FIG. 10 is a plan view showing a bottom surface of a lid of an apparatus for processing a substrate according to a first embodiment of the present invention;

FIG. 11 is a perspective view showing a housing of an apparatus for processing a substrate according to a first embodiment of the present invention;

FIG. 12 is a cross-sectional view showing an apparatus for processing a substrate according to a second embodiment of the present invention;

FIG. 13 is a perspective view showing a lid of an apparatus for processing a substrate according to a second embodiment of the present invention;

FIG. 14 is a magnified view of portion B of FIG. 12;

FIG. 15 is a perspective view showing a plurality of first gas injecting means of an apparatus for processing a substrate according to a second embodiment of the present invention;

FIG. 16 is a perspective view showing a plurality of gas second injecting means of an apparatus for processing a substrate according to a second embodiment of the present invention; and

FIG. 17 is a plan view showing a bottom surface of a lid of an apparatus for processing a substrate according to a second embodiment of the present invention.

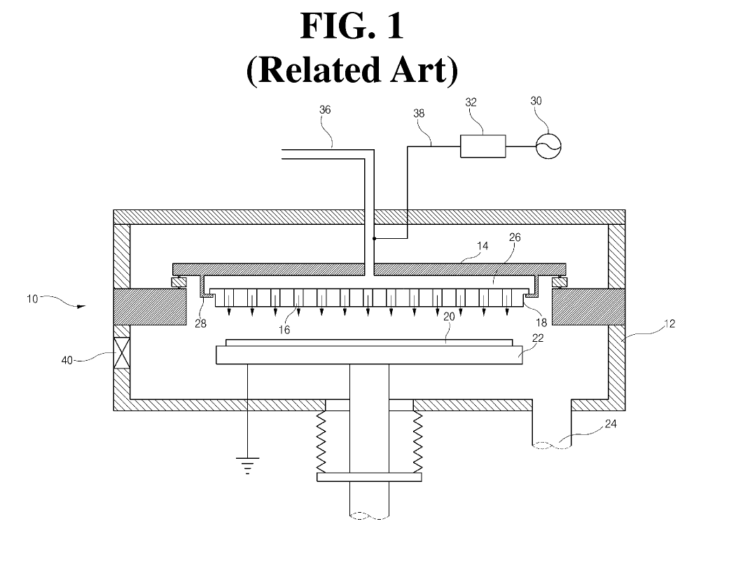

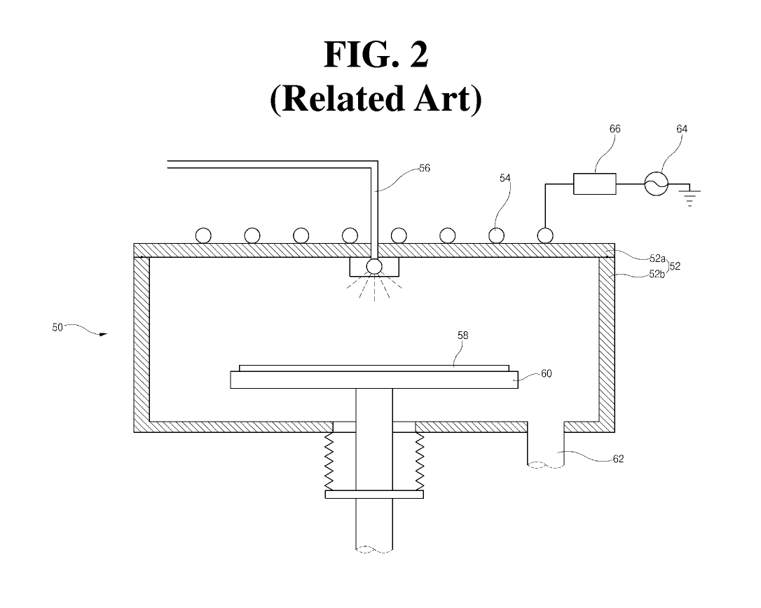

### DETAILED DESCRIPTION OF THE PREFERRED EMBODIMENTS

Reference will now be made in detail to embodiments which are illustrated in the accompanying drawings. Wherever possible, similar reference numbers will be used to refer to the same or similar parts.

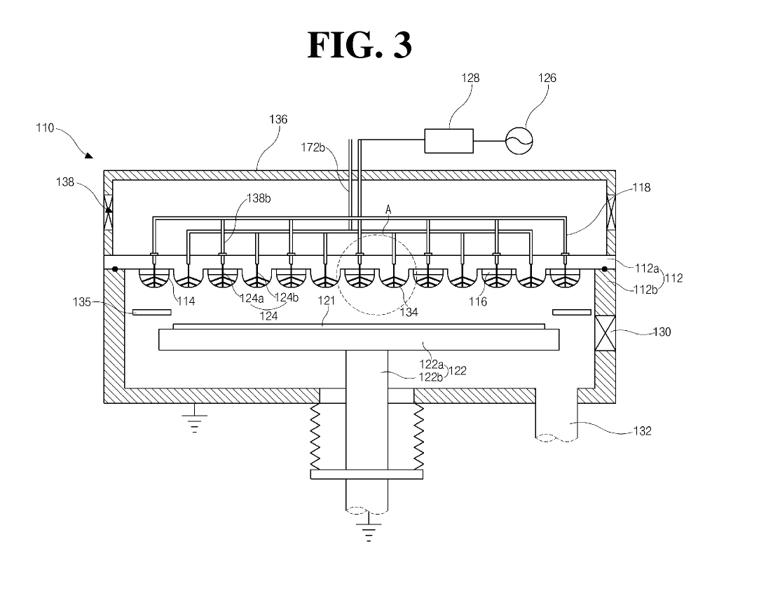

FIG. 3 is a cross-sectional view showing an apparatus for processing a substrate according to a first embodiment of the present invention.

In FIG. 3, a capacitively coupled plasma (CCP) type apparatus 110 includes a process chamber 112 having a lid 112a and a body 112b and providing a reaction space by combination of the lid 112a and the body 112b, a plurality of plasma source electrodes 114 on an inner surface of the lid 112a, a plurality of protruding portions 134 between the adjacent plasma source electrodes 114 and protruding from the lid 112a, a plurality of feeding lines 118 on an outer surface of the lid 112a and connected to the plurality of plasma source electrodes 114, a gas injecting means 124 in each of the plurality of plasma source electrodes 114 and the plurality of protruding portions 134, and a susceptor 122 as a plasma ground electrode in the reaction space and having a substrate 120 thereon.

The CCP type apparatus 110 may further include a housing 136 over the lid 112a, a gate 130 for transferring the substrate 120 to and from the process chamber 112, an exhaust 132 for outputting a reaction gas and a residual product from the process chamber 112, and an edge frame 135 for preventing deposition of a thin film or etching of a thin film in a boundary portion of the substrate 120.

The housing 136 is disposed over the lid 112a and provides a closed space where the plurality of feeding lines 118 connecting the plurality of plasma source electrodes 114 and the RF power supply 126 are disposed. The edge frame 135 extends from an inner surface of a sidewall of the process chamber 112 to the boundary portion of the substrate 120. In addition, the edge frame 135 is electrically insulated to have a floating state.

For the purpose of preventing a standing wave effect, each of the plurality of plasma source electrodes 114 has a size (width) smaller than a wavelength of an RF wave. A plurality of insulating plates 116 for electric insulation are formed between each of the plurality of plasma source electrodes 114 and the lid 112a. Although not shown in FIG. 3, the lid 112a, each of the plurality of insulating plates 116 and each of the plurality of plasma source electrodes 114 are combined with each other using a connecting means such as a bolt and a nut.

The lid 112a, the body 112b and the susceptor 122 are grounded and used as a plasma ground electrode corresponding to the plurality of plasma source electrodes 114. The lid 112a, the body 112b, the susceptor 122 and the plurality of plasma source electrodes 114 may be formed of a metallic material such as aluminum and stainless steel, and the plurality of insulating plates 116 may be formed of a ceramic material.

The susceptor 122 includes a supporting plate 122a where the substrate 120 is loaded and a shaft 122b moving up and down the supporting plate 122a. The supporting plate 122a may have an area greater than the substrate 120. The susceptor 122 may be grounded similarly to the process chamber 112. According to a condition for processing the substrate, in another embodiment, an independent RF power may be applied to the susceptor 122 or the susceptor 122 may have a floating state.

The gas injecting means 124 includes a plurality of first gas injecting means 124a in the plurality of plasma source electrodes 114 and a plurality of second gas injecting means 124b in the plurality of protruding portions 134. A first process gas or a first process gas composition is supplied through the plurality of first gas injecting means 124a, and a second process gas or a second process gas composition is supplied through the plurality of second gas injecting means 124b.

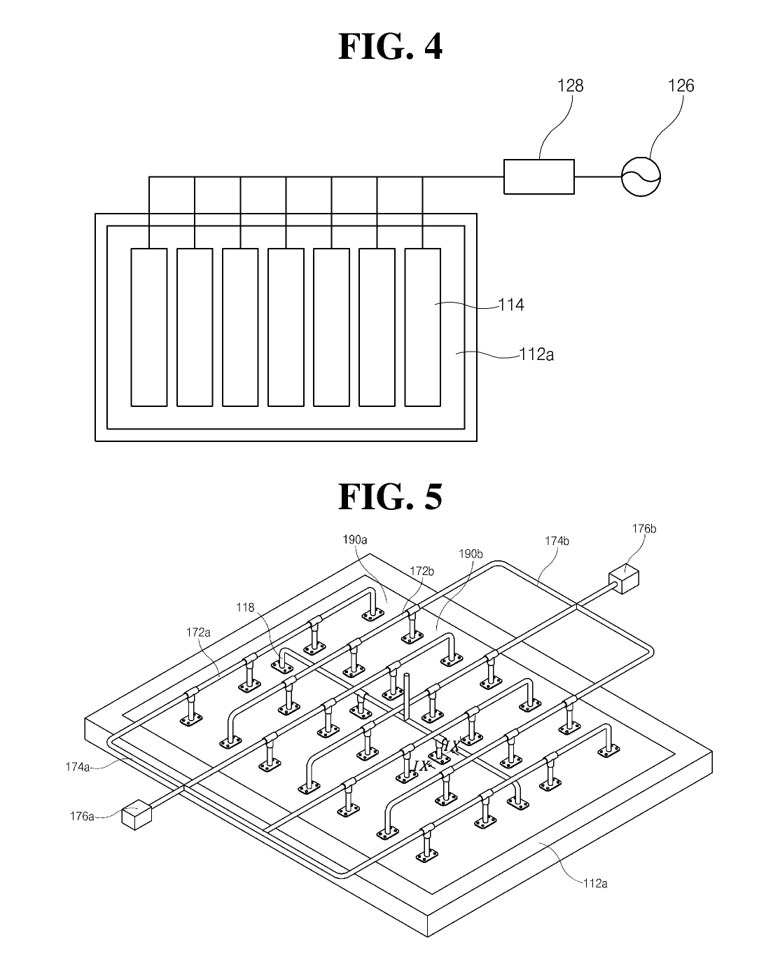

FIG. 4 is a plan view showing a plurality of plasma source electrodes of an apparatus for processing a substrate according to a first embodiment of the present invention.

In FIG. 4, the plurality of plasma source electrodes 114 are connected to the RF power supply 126 in parallel, and a matcher 128 for matching an impedance is connected between the plurality of plasma source electrodes 114 and the RF power supply 126. The RF power supply 126 may use an RF wave having a very high frequency (VHF) within a range of about 20 MHz to about 50 MHz for excellent efficiency in plasma generation. Each of the plurality of plasma source electrodes 114 may have a rectangular shape having a longer side and a shorter side. In addition, the plurality of plasma source electrodes 114 may be parallel to and spaced apart from each other by an equal distance.

FIG. 5 is a perspective view showing a lid of an apparatus for processing a substrate according to a first embodiment of the present invention.

In FIG. 5, the lid 112a includes a plurality of first areas 190a corresponding to the plurality of plasma source electrodes 114 (of FIG. 3) and a plurality of second areas 190b corresponding to the plurality of protruding portions 134 (of FIG. 3). The plurality of first gas injecting means 124a (of FIG. 3) are formed through the lid 112a of the plurality of first areas 190a, the plurality of plasma source electrodes 114 and the plurality of insulating plates 116 (of FIG. 3), and the plurality of second gas injecting means 124b are formed through the lid 112a in the plurality of second areas 190b and the plurality of protruding portions 134.

Central portions of the plurality of plasma source electrodes 114 are connected to the RF power supply 126 (of FIG. 3) through the plurality of feeding lines 118. In another embodiment, the plurality of feeding lines 118 may be connected to both end portions of each of the plurality of plasma source electrodes 114 or may be connected to the other portion of each of the plurality of plasma source electrodes 114.

A first gas supplying pipe 172a is disposed over the lid 112a corresponding to the plurality of first plasma source electrodes 114. The first gas supplying pipe 172a is connected to a plurality of first sub gas supplying pipes 138a and connected to a first source part 176a through a first transferring pipe 174a to supply the first process gas or the first process gas composition.

Further, a second gas supplying pipe 172b is disposed over the lid 112a corresponding to the plurality of protruding portions 134. The second gas supplying pipe 172b is connected to a plurality of second sub gas supplying pipes 138b and connected to a second source part 176b through a second transferring pipe 174b to supply the second process gas or the second process gas composition.

The first and second transferring pipes 174a and 174b are connected to the first and second gas supplying pipes 172a and 172b, respectively, in the closed space of the housing 136 (of FIG. 3) and connected to the first and second source parts 176a and 176, respectively, through a sidewall of the housing 136.

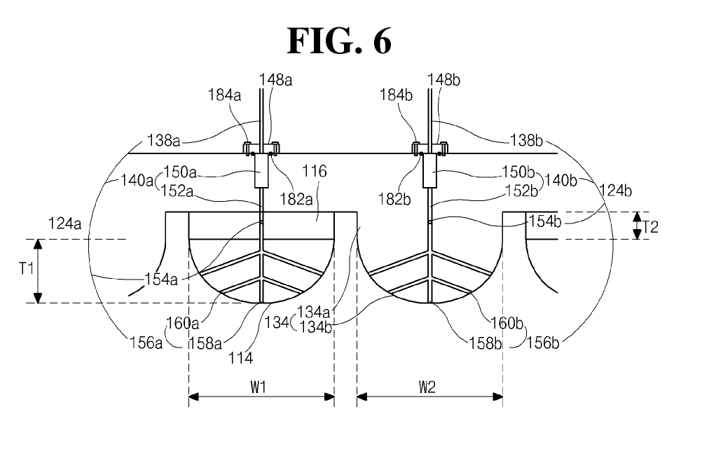

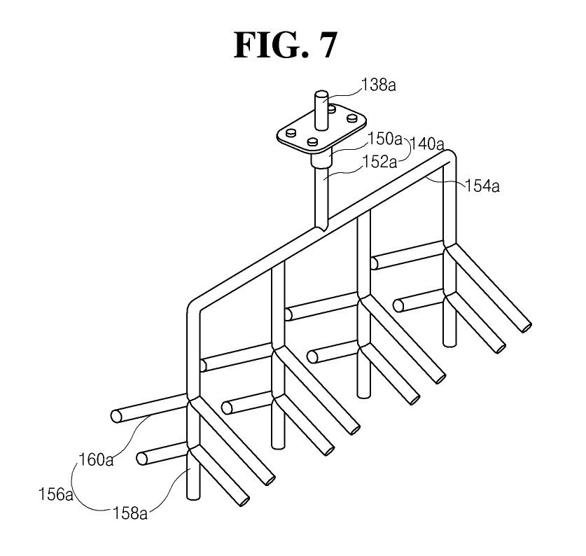

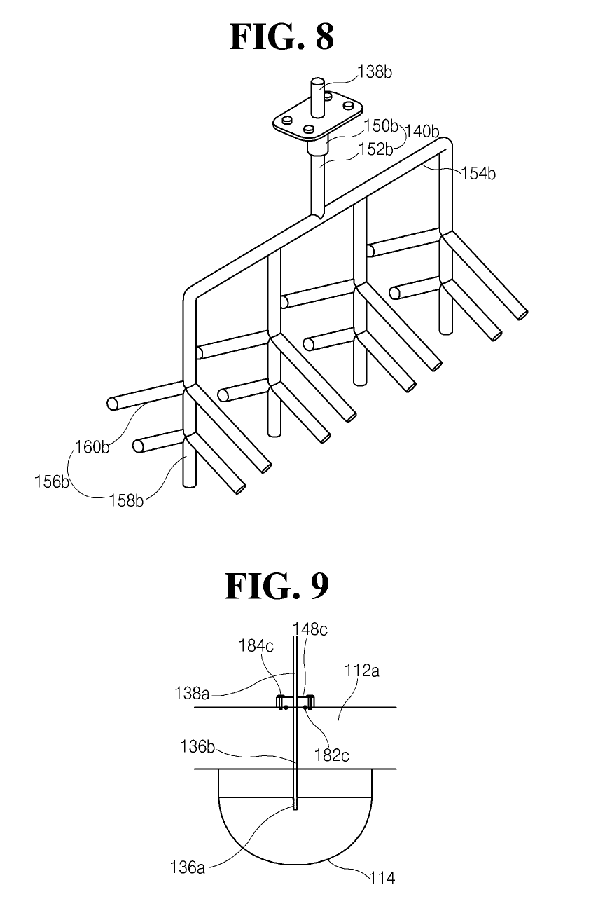

FIG. 6 is a magnified view of portion A of FIG. 3, FIGS. 7 and 8 are perspective views showing a plurality of first gas injecting means and a plurality of second gas injecting means, respectively, of an apparatus for processing a substrate according to a first embodiment of the present invention.

In FIG. 6, the plurality of insulating plates 116 and the plurality of plasma source electrodes 114 are sequentially formed on the inner surface of the lid 112a (of FIG. 3), and the plurality of protruding portions 134 protruding from the lid 112a are formed between the adjacent plasma source electrodes 114. The plurality of plasma source electrodes 114 and the plurality of protruding portions 134 alternate with each other.

The gas injecting means 124 includes the plurality of first gas injecting means 124a that are formed in the plurality of plasma source electrodes 114 and supply the first process gas or the first process gas composition and the plurality of second gas injecting means 124b that are formed in the plurality of protruding portions 134 and supply the second process gas or the second process gas composition.

Each of the plurality of first gas injecting means 124a includes the first sub gas supplying pipe 138a supplying the first process gas or the first process gas composition, a first gas inlet pipe 140a that is connected to the first sub gas supplying pipe 138a and is formed through the lid 112a corresponding to each plasma source electrode 114 and each insulating plate 116, a first inner connecting pipe 154a connected to the first gas inlet pipe 140a and a plurality of first injecting pipes 156a branching out from the first inner connecting pipe 154a.

The first sub gas supplying pipe 138a is connected to the first gas inlet pipe 140a by combining a first contact plate 148a and the lid 112a with a first O-ring 182a interposed therebetween using a first bolt 184a.

The first gas inlet pipe 140a includes a first insulating pipe 150a and a first connecting pipe 152a connected to the first insulating pipe 150a. Since the lid 112a is formed of a metallic material such as aluminum (Al), a plasma may be discharged at a contact portion between the first sub gas supplying pipe 138a and the lid 112a. For the purpose of preventing the plasma discharge, the first sub gas supplying pipe 138a is connected to the first insulating pipe 150a formed of a ceramic material.

As shown in FIG. 7, the first inner connecting pipe 154a extends along the longer side of each plasma source electrode 114 under the first connecting pipe 152a. The first inner connecting pipe 154a is disposed to be parallel to the susceptor 122 and perpendicular to the first connecting pipe 152a of the first gas inlet pipe 140a. Since the first inner connecting pipe 154a extends toward two directions under the first gas inlet pipe 140a and the plurality of first injecting pipes 156a are connected to the first inner connecting pipe 154a, the first process gas or the first process gas composition is uniformly injected into the reaction space.

The plurality of first injecting pipes 156a includes a plurality of first vertical injecting pipes 158a connected to the first inner connecting pipe 154a and a plurality of first slant injecting pipes 160a branching from each first vertical injecting pipes 158a. In another embodiment, the plurality of first slant injecting pipes 160a may be further divided. The plurality of first slant injecting pipes 160a have a symmetrical shape with respect to each first vertical injecting pipe 158a. A slant angle between each first vertical injecting pipes 158a and each first slant injecting pipes 160a may be controlled such that the plurality of first slant injecting pipes 160a are uniformly disposed along a surface of each plasma source electrode 114.

Each first injecting pipe 156a may have a diameter within a range of about 0.5 mm to about 1 mm. Each first vertical injecting pipe 158a may include upper and lower portions, and the upper portion of each first vertical injecting pipe 158a where the plurality of first slant injecting pipes 160a branch out may have a diameter greater than the lower portion of each first vertical injecting pipe 158a where the process gas is injected to the reaction space. The plurality of first injecting pipes 156a are disposed along the surface of each plasma source electrode 114 by an equal gap distance. In addition, at least two first slant injecting pipes 160a may be connected to one side of each first vertical injecting pipe 158a. The first process gas or the first process gas composition may be uniformly injected into the reaction space due to the plurality of first injecting pipes 156a having a uniform distribution.

As shown in FIG. 6, each protruding portion 134 includes an upper protruding portion 134a vertically extending from the lid 112a and a lower protruding portion 134b expanding from the upper protruding portion 134a. The upper protruding portion 134a may have the same thickness as each insulating plate 116. Each of the plurality of protruding portions 134 and the plurality of plasma source electrodes 114 may have a half circle or a half ellipse in a cross-sectional view. Each plasma source electrode 114 has a first thickness T1 and a first width W1, and each lower protruding portion 134b has a second thickness T2 and a second width W2.

Each plasma source electrode 114 and each lower protruding portion 134b may be formed such that the first thickness T1 is the same as the second thickness T2 and the first width W1 is the same as the second width W2. As a result, a first distance between each plasma source electrode 114 and the susceptor 122 may be the same as a second distance between each lower protruding portion 134b and the susceptor 122. In another embodiment, each plasma source electrode 114 and each lower protruding portion 134b may be formed such that the first thickness T1 is different from the second thickness T2 and the first width W1 is different from the second width W2 based on a diffusion distance of the first process gas, the first process gas composition, the second process gas or the second process gas composition, or a process condition.

As shown in FIGS. 6 and 8, each of the plurality of second gas injecting means 124b includes a second sub gas supplying pipe 138b supplying the second process gas or the second process gas combination, a second gas inlet pipe 140b that is connected to the second sub gas supplying pipe 138b and is formed through the lid 112a corresponding to each protruding portion 134, a second inner connecting pipe 154b connected to the second gas inlet pipe 140b and a plurality of second injecting pipes 156b branching out from the second inner connecting pipe 154b.

The second sub gas supplying pipe 138b is connected to the second gas inlet pipe 140b by combining a second contact plate 148b and the lid 112a corresponding to each protruding portion 134 with a second O-ring 182b interposed therebetween using a second bolt 184b.

The second gas inlet pipe 140b includes a second insulating pipe 150b and a second connecting pipe 152b connected to the second insulating pipe 150b. Since the lid 112a is formed of a metallic material such as aluminum (Al), a plasma may be discharged at a contact portion between the second sub gas supplying pipe 138b and the lid 112a. For the purpose of preventing the plasma discharge, the second sub gas supplying pipe 138b is connected to the second insulating pipe 150b formed of a ceramic material.

The second inner connecting pipe 154b extends along the longer side of each plasma source electrode 114 under the second connecting pipe 152b. The second inner connecting pipe 154b is disposed to be parallel to the susceptor 122 and perpendicular to the second connecting pipe 152b. Since the second inner connecting pipe 154b extends toward two directions under the second gas inlet pipe 140b and the plurality of second injecting pipes 156b are connected to the second inner connecting pipe 154b, the second process gas or the second process gas composition is uniformly injected into the reaction space.

The plurality of second injecting pipes 156b includes a plurality of second vertical injecting pipes 158b connected to the second inner connecting pipe 154b and a plurality of second slant injecting pipes 160b branching from each second vertical injecting pipes 158b. The plurality of second slant injecting pipes 160b have a symmetrical shape with respect to each second vertical injecting pipes 158b. A slant angle between each second vertical injecting pipes 158b and each second slant injecting pipes 160b may be controlled such that the plurality of second slant injecting pipes 160b are uniformly disposed along a surface of each lower protruding portion 134b.

Each second injecting pipe 156b may have a diameter within a range of about 0.5mm to about 1mm. Each second vertical injecting pipe 158b may include upper and lower portions, and the upper portion of each second vertical injecting pipe 158b where the plurality of second slant injecting pipes 160b branch out may have a diameter greater than the lower portion of each second vertical injecting pipe 158b where the process gas is injected to the reaction space. The plurality of second injecting pipes 156b are disposed along the surface of each lower protruding portion 134b by an equal gap distance. In addition, at least two second slant injecting pipes 160b may be connected to one side of each second vertical injecting pipe 158b. The second process gas or the second process gas composition may be uniformly injected into the reaction space due to the plurality of second injecting pipes 156b having a uniform distribution.

FIG. 9 is a cross-sectional view taken along a line IX-IX of FIG. 5.

In FIG. 9, each plasma source electrode 114 includes a connecting hole 136a, and the lid 112a and each insulating plate 116 include an input hole 136b corresponding to the connecting hole 136a. Each feeding line 118 (of FIG. 3) is inserted through the connecting hole 136a and the input hole 136b so that the plurality of feeding lines 118 (of FIG. 3) can be electrically connected to the plurality of plasma source electrodes 114, respectively. Each feeding line 118 is electrically connected to each plasma source electrode 114 by combining a third contact plate 148c and the lid 112a corresponding to each plasma source electrode 114 with a third O-ring 182c interposed therebetween using a third bolt 184c. A screw thread may be formed on an inner surface of the connecting hole 136a and on an outer surface of each feeding line 118 corresponding to the connecting hole 136a.

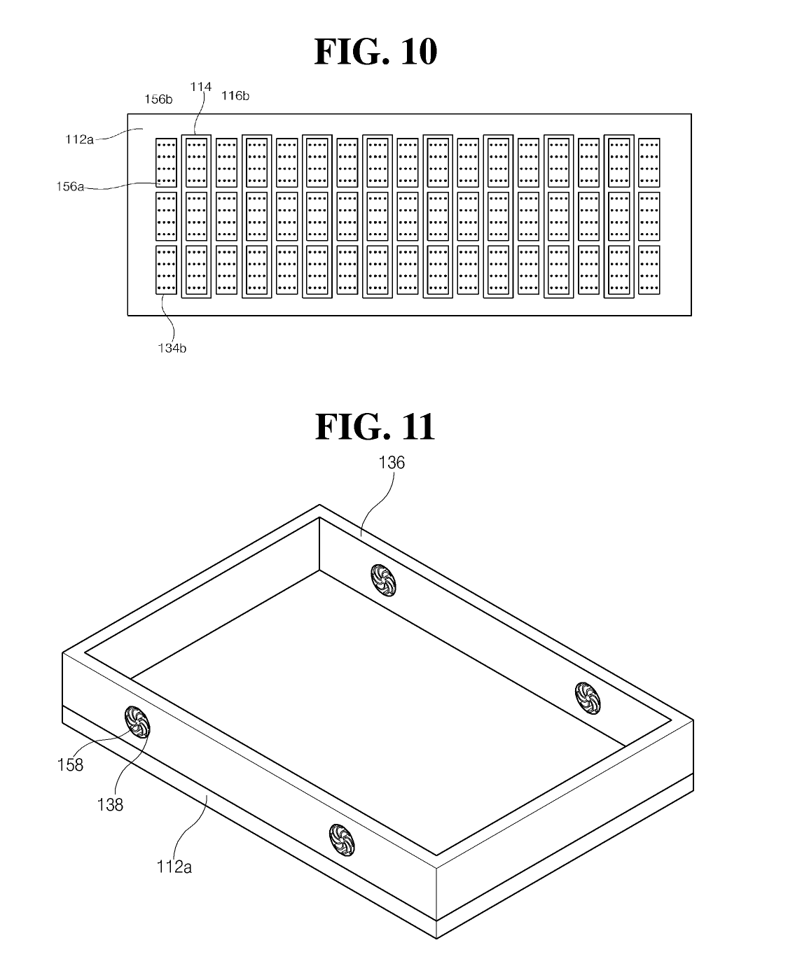

FIG. 10 is a plan view showing a bottom surface of a lid of an apparatus for processing a substrate according to a first embodiment of the present invention.

In FIG. 10, the plurality of first injecting pipes 156a of each first gas injecting means 124a (of FIG. 6) and the plurality of second injecting pipes 156b of each second gas injecting means 124b (of FIG. 6) are uniformly disposed throughout the entire bottom surface of the lid 112a, and the process gas is supplied to the reaction space uniformly and radially. Since a blind spot where the process gas is not supplied does not exist in the process chamber 112, a thin film is uniformly formed on the substrate 120 or a thin film on the substrate 120 is uniformly patterned.

The first and second process gases or process gas compositions may include the same material as or the different material from each other. When the first and second process gases or the process gas compositions have the different material as each other, each first gas injecting means 124a formed in each plasma source electrode 114, each insulating plate 116 and the lid 112a may supply the gas that is activated by the plasma and each second gas injecting means 124b formed in each protruding portion 134 and the lid 112a may supply the gas that is ionized to form the plasma. In another embodiment, each first gas injecting means 124a may supply the gas that is ionized and each second gas injecting means 124b may supply the gas that is activated.

FIG. 11 is a perspective view showing a housing of an apparatus for processing a substrate according to a first embodiment of the present invention.

Since the plurality of feeding lines 118 (of FIG. 3) connected to the RF power supply 126 (of FIG. 3) radiate heat and the heat is accumulated in the closed space defined by the housing 136 and the lid 112a of the CCP type apparatus 110 (of FIG. 3), the closed space should be cooled. In FIG. 11, a cooling means including a plurality of air holes 138 and a plurality of fans 158 in the plurality of air holes 138 is formed in the housing 136. In another embodiment, the closed space may be cooled by various cooling means different from the plurality of air holes 138 and the plurality of fans 158.

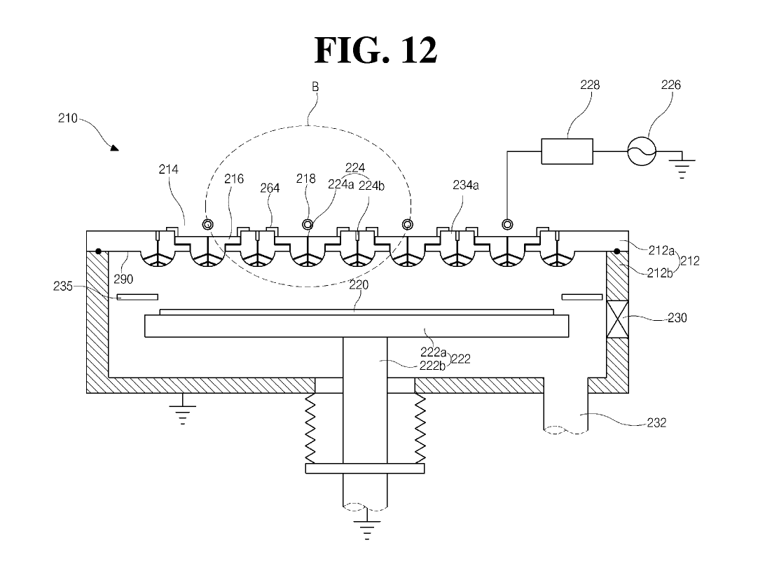

FIG. 12 is a cross-sectional view showing an apparatus for processing a substrate according to a second embodiment of the present invention.

In FIG. 12, an inductively coupled plasma (ICP) type apparatus 210 includes a process chamber 212 having a lid 212a and a body 212b and providing a reaction space by combination of the lid 212a and the body 212b, a plurality of insulating plates 216 sealing a plurality of open portions 214 of the lid 212a, a plurality of antennas 218 over the plurality of insulating plates 216, a gas injecting means 224 in each of the lid 212a and the plurality of insulating plates 216, and a susceptor 222 in the reaction space and having a substrate 220 thereon.

The ICP type apparatus 210 may further include a gate 230 for transferring the substrate 220 to and from the process chamber 212, an exhaust 232 for outputting a reaction gas and a residual product from the process chamber 212, and an edge frame 235 for preventing deposition of a thin film or etching of a thin film in a boundary portion of the substrate 220. The edge frame 235 extends from an inner surface of a sidewall of the process chamber 212 to the boundary portion of the substrate 220. In addition, the edge frame 235 is electrically insulated to have a floating state.

The plurality of antennas 218 are connected to an RF power supply 226 in parallel, and a matcher 228 for matching an impedance is connected between the plurality of antennas 218 and the RF power supply 226. The plurality of antennas 218 where an RF power is applied is used as a plasma source electrode, and the lid 212a and the body 212b grounded is used as a plasma ground electrode corresponding to the plasma source electrode. The lid 212a and the body 212b may be formed of a metallic material such as aluminum and stainless steel, and the plurality of insulating plates 216 may be formed of a ceramic material.

The susceptor 222 includes a supporting plate 222a where the substrate 220 is loaded and a shaft 222b moving up and down the supporting plate 222a. The supporting plate 222a may have an area greater than the substrate 220. The susceptor 222 may be grounded similarly to the process chamber 212. According to a condition for processing the substrate, in another embodiment, an independent RF power may be applied to the susceptor 222 or the susceptor 222 may have a floating state.

The gas injecting means 224 includes a plurality of first gas injecting means 224a in the plurality of insulating plates 216 and a plurality of second gas injecting means 224b in a plurality of upper protruding portions 234a of the lid 212a.

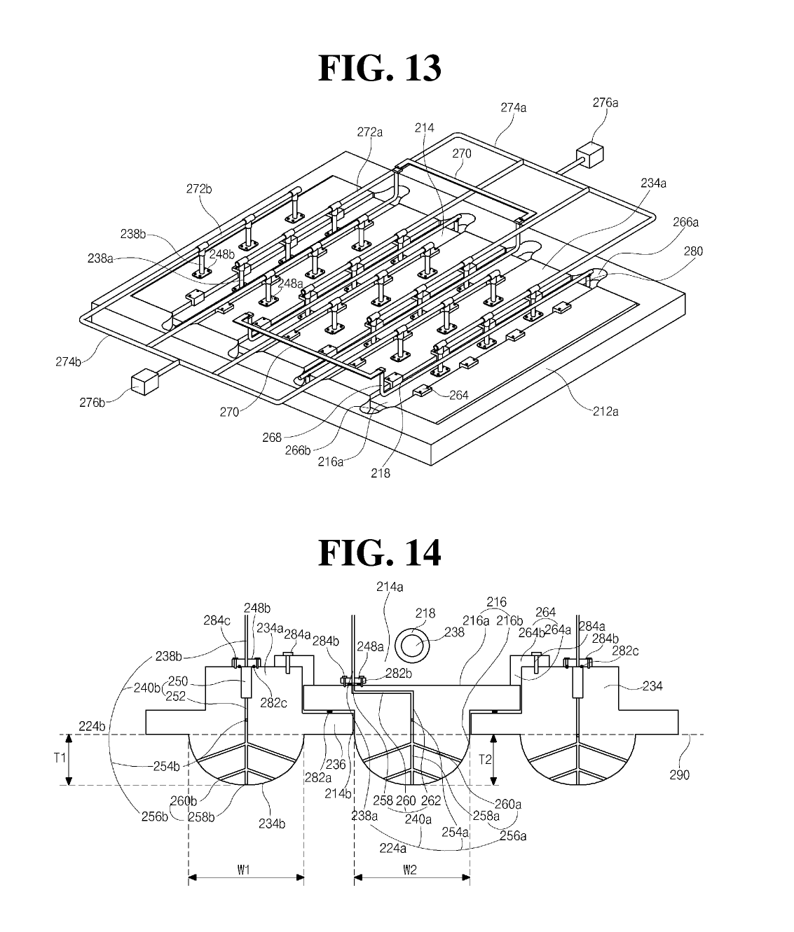

FIG. 13 is a perspective view showing a lid of an apparatus for processing a substrate according to a second embodiment of the present invention.

In FIG. 13, a plurality of upper portions 216a of the plurality of insulating plates 216 (of FIG. 12) and the plurality of upper protruding portions 234a of the lid 212a are alternately disposed to be parallel to the plurality of open portions 214 of the lid 212a. The plurality of first gas injecting means 224a (of FIG. 12) are formed through the plurality of upper portions 216a of the plurality of insulating plates 216, and the plurality of second gas injecting means 224b are formed through the plurality of upper protruding portions 234a of the lid 212a.

The plurality of open portions 214 penetrate the lid 212a and are disposed to be parallel to and spaced apart from each other. Each open portion 214 may have a rectangular shape having a longer side and a shorter side. First and second openings 266a and 266b are formed at end portions of each open portion 214, and the first and second openings 266a and 266b may not penetrate the lid 212a.

Each antenna 218 includes a first end portion connected to the RF power supply 226 (of FIG. 12) and a second end portion grounded. A floating rod 280 for electrically floating the first end portion of each antenna 218 is disposed over the first opening 266a and a grounding rod 268 for electrically grounding the second end portion of each antenna 218 is disposed over the second opening 266b. The grounding rod 268 connected to the plurality of second end portions of the plurality of antennas 218 is connected to a grounding portion 270. Since the first end portion of each antenna 218 is supported by the floating rod 280 and the second end portion of each antenna 218 is held by the grounding rod 268 connected to the grounding portion 270, each antenna 218 is spaced apart from the plurality of upper portions 216a of the plurality of insulating plates 216 without contact.

The first end portion of each antenna 218 connected to the floating rod 280 and the second end portion of each antenna 218 connected to the grounding rod 268 are alternately disposed over the lid 212a. For example, the first end portion of the odd numbered antenna 218 may be supported by the floating rod 280 at one side of the lid 212a, and the second end portion of the even numbered antenna 218 may be connected to the grounding portion 270 through the grounding rod 268 at an opposite side of the lid 212a. The first and second openings 266a and 266b may be oppositely disposed according to the positions of the first and second end portions of each antenna 218.

A first gas supplying pipe 272a is disposed over the upper portion 216a of each insulating plate 216. The first gas supplying pipe 272a is connected to a plurality of first sub gas supplying pipes 238a and connected to a first source part 276a through a first transferring pipe 274a to supply the first process gas or the first process gas composition.

Further, a second gas supplying pipe 272b is disposed over the upper protruding portion 234a of the lid 212a. The second gas supplying pipe 272a is connected to a plurality of second sub gas supplying pipes 238b and connected to a second source part 276b through a second transferring pipe 274b to supply the second process gas or the second process gas composition.

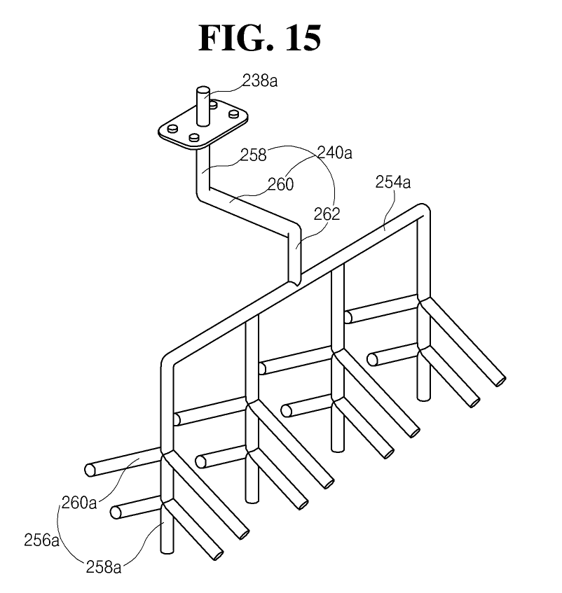

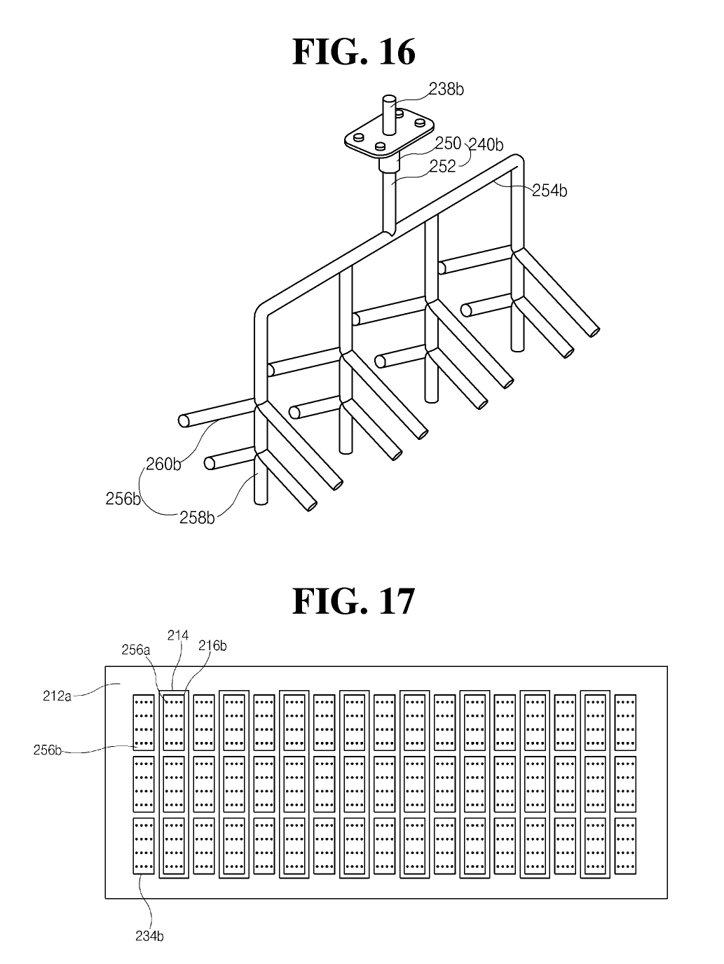

FIG. 14 is a magnified view of portion B of FIG. 12, FIGS. 15 and 16 are perspective views showing a plurality of first gas injecting means and a plurality of gas second injecting means, respectively, of an apparatus for processing a substrate according to a second embodiment of the present invention.

In FIG. 14, each open portion 214 includes an upper open portion 214a having each insulating plate 216 therein and a lower open portion 214b corresponding to a second lower protruding portion 216b of each insulating plate 216. The lid 212a includes the plurality of upper protruding portions 234a exposed to an exterior of the process chamber 212 and disposed between the adjacent open portions 214, a plurality of first lower protruding portions 234b disposed in the reaction space of the process chamber 212 and facing the susceptor 222, and a plurality of supporting portions 236 extending from the plurality of upper protruding portions 234a and the plurality of first lower protruding portions 234b and supporting the plurality of insulating plates 216. Each first lower protruding portion 234b vertically protrudes from a reference surface 290 of the lid 212a and has a round shape having a first thickness T1 and a first width W1. For example, each first lower protruding portion 234b may have a half circle or a half ellipse in a cross-sectional view.

Each insulating plate 216 includes an upper portion 216a exposed to the exterior of the process chamber 212 and corresponding to each antenna 218 and a second lower protruding portion 216b disposed in the reaction space of the process chamber 212 and facing the susceptor 222. The second lower protruding portion 216b is disposed between the two adjacent first lower protruding portions 234b. A distance between the two adjacent first lower protruding portions 234b may be the same as a distance between the two adjacent second lower protruding portions 216b. The second lower protruding portion 216b vertically protrudes from the reference surface 290 of the lid 212a and has a round shape having a second thickness T2 and a second width W2.

Each first lower protruding portion 234b and each second lower protruding portion 216b may be formed such that the first thickness T1 is the same as the second thickness T2 and the first width W1 is the same as the second width W2. As a result, a first distance between each first lower protruding portion 234b and the susceptor 222 may be the same as a second distance between each second lower protruding portion 216b and the susceptor 222. In another embodiment, each first lower protruding portion 234b and each second lower protruding portion 216b may be formed such that the first thickness T1 is different from the second thickness T2 and the first width W1 is different from the second width W2 based on a diffusion distance of the first process gas, the first process gas composition, the second process gas or the second process gas composition, or a process condition.

The plurality of upper protruding portions 234a of the lid 212a and the plurality of upper portions 216a of the plurality of insulating plates 216 are alternately disposed, and the plurality of first lower protruding portions 234b corresponding to the plurality of upper protruding portions 234a and the plurality of second lower protruding portions 216b corresponding to the plurality of upper portions 216a are alternately disposed. Each antenna 218 is disposed over and spaced apart from each insulating plate 216. In addition, each antenna 218 may include a path 238 for a refrigerant.

Each insulating plate 216 is inserted into each upper open portion 214a and a first O-ring 282a is interposed between each upper portion 216a and each supporting portion 236. The first O-ring 282a is disposed to correspond to a boundary region of each upper portion 216a. Each insulating plate 216 may be fixed by a fixing means 264 contacting the boundary region of each upper portion 216a and each upper protruding portion 234a. For example, a plurality of fixing means 264 may be formed on side portions of each upper portion 216a.

The fixing means 264 includes a vertical fixing portion 264a contacting the boundary region of each upper portion 216a and a horizontal fixing portion 264b horizontally extending from the vertical fixing portion 264a and disposed over each upper protruding portion 234a. When the horizontal fixing portion 264b and each upper protruding portion 234a area combined by a first bolt 284a, a pressure is transmitted to the upper portion 216a of each insulating plate 216 through the vertical fixing portion 264a. As a result, the upper portion 216a of each insulating plate 216 and each supporting portion 236 of the lid 212a are tightly sealed with the first O-ring 282a interposed therebetween.

As shown in FIGS. 14 to 16, the gas injecting means 224 includes the plurality of first gas injecting means 224a that are formed in the plurality of insulating plates 216 and supply the first process gas or the first process gas composition and the plurality of second gas injecting means 224b that are formed in the plurality of upper protruding portions 234a of the lid 212a and supply the second process gas or the second process gas composition.

Each of the plurality of first gas injecting means 224a includes the first sub gas supplying pipe 238a supplying the first process gas or the first process gas composition, a first gas inlet pipe 240a that is connected to the first sub gas supplying pipe 238a and is formed in each insulating plate 216, a first inner connecting pipe 254a connected to the first gas inlet pipe 240a and a plurality of first injecting pipes 256a branching out from the first inner connecting pipe 254a.

Since each antenna 218 is disposed over a central region of each upper portion 216a of each insulating plate 216, the first sub gas supplying pipe 238a may be inserted into an edge region of each upper portion 216a spaced apart from the central region. The first sub gas supplying pipe 238a is connected to the first gas inlet pipe 240a by combining a first contact plate 248a and each upper portion 216a of each insulating plate 216 with a second O-ring 282b interposed therebetween using a second bolt 284b. The first gas inlet pipe 240a includes a first vertical inlet pipe 258 connected to the first sub gas supplying pipe 238a, a horizontal inlet pipe 260 connected to the first vertical inlet pipe 258 and a second vertical inlet pipe 262 connected to the horizontal inlet pipe 260. The second vertical inlet pipe 262 is disposed at the central region of the upper portion 216a.

For the purpose of forming the first vertical inlet pipe 258, the horizontal inlet pipe 260 and the second vertical inlet pipe 262 in each insulating plate 216, each insulating plate 216 may be formed by combining a plurality of first ceramic plates having a vertical hole and a plurality of second ceramic plates having a horizontal groove.

The first inner connecting pipe 254a extends along the longer side of each open portion 214 under the second vertical inlet pipe 258. The first inner connecting pipe 254a is disposed to be parallel to the susceptor 222 and perpendicular to the first gas inlet pipe 240a. Since the first inner connecting pipe 254a extends toward two directions under the first gas inlet pipe 240a and the plurality of first injecting pipes 256a are connected to the first inner connecting pipe 254a, the first process gas or the first process gas composition is uniformly injected into the reaction space.

The plurality of first injecting pipes 256a includes a plurality of first vertical injecting pipes 258a connected to the first inner connecting pipe 254a and a plurality of first slant injecting pipes 260a branching from each first vertical injecting pipes 258a. The plurality of first slant injecting pipes 260a have a symmetrical shape with respect to each first vertical injecting pipes 258a. A slant angle between each first vertical injecting pipes 258a and each first slant injecting pipes 260a may be controlled such that the plurality of first slant injecting pipes 260a are uniformly disposed along a surface of each second lower protruding portion 216b.

Each first injecting pipe 256a may have a diameter within a range of about 0.5mm to about 1mm. Each first vertical injecting pipe 258a may include upper and lower portions, and the upper portion of each first vertical injecting pipe 258a where the plurality of first slant injecting pipes 260a branch out may have a diameter greater than the lower portion of each first vertical injecting pipe 258a where the process gas is injected to the reaction space. The plurality of first injecting pipes 256a are disposed along the surface of each second lower protruding portion 216b by an equal gap distance. In addition, at least two first slant injecting pipes 260a may be connected to one side of each first vertical injecting pipe 258a. The first process gas or the first process gas composition may be uniformly injected into the reaction space due to the plurality of first injecting pipes 256a having a uniform distribution.

Each of the plurality of second gas injecting means 224b includes a second sub gas supplying pipe 238b supplying the second process gas or the second process gas combination, a second gas inlet pipe 240b that is connected to the second sub gas supplying pipe 238b and is formed in each upper protruding portion 234a of the lid 212a, a second inner connecting pipe 254b connected to the second gas inlet pipe 240b and a plurality of second injecting pipes 256b branching out from the second inner connecting pipe 254b.

The second sub gas supplying pipe 238b is inserted into a central region of each upper portion 234a. The second sub gas supplying pipe 238b is connected to the second gas inlet pipe 240b by combining a second contact plate 248b and each upper protruding portion 234a with a third O-ring 282c interposed therebetween using a third bolt 284c.

The second gas inlet pipe 240b includes an insulating pipe 250 and a connecting pipe 252 connected to the insulating pipe 250. Since the lid 212a is formed of a metallic material such as aluminum (Al), a plasma may be discharged at a contact portion between the second sub gas supplying pipe 238b and the lid 212a. For the purpose of preventing the plasma discharge, the second sub gas supplying pipe 238b is connected to the insulating pipe 250b formed of a ceramic material.

The second inner connecting pipe 254b extends along the longer side of each open portion 214 under the connecting pipe 252. The second inner connecting pipe 254b is disposed to be parallel to the susceptor 222 and perpendicular to the second gas inlet pipe 240b. Since the second inner connecting pipe 254b extends toward two directions under the second gas inlet pipe 240b and the plurality of second injecting pipes 256b are connected to the second inner connecting pipe 254b, the second process gas or the second process gas composition is uniformly injected into the reaction space.

The plurality of second injecting pipes 256b includes a plurality of second vertical injecting pipes 258b connected to the second inner connecting pipe 254b and a plurality of second slant injecting pipes 260b branching from each second vertical injecting pipes 258b. The plurality of second slant injecting pipes 260b have a symmetrical shape with respect to each second vertical injecting pipes 258b. In another embodiment, the plurality of second slant injecting pipes 260b may be further divided. The plurality of second slant injecting pipes 260b have a symmetrical shape with respect to each second vertical injecting pipe 258b. A slant angle between each second vertical injecting pipes 258b and each second slant injecting pipes 260b may be controlled such that the plurality of second slant injecting pipes 260b are uniformly disposed along a surface of each first lower protruding portion 234b.

Each second injecting pipe 256b may have a diameter within a range of about 0.5mm to about 1mm. Each second vertical injecting pipe 258b may include upper and lower portions, and the upper portion of each second vertical injecting pipe 258b where the plurality of second slant injecting pipes 260b branch out may have a diameter greater than the lower portion of each second vertical injecting pipe 258b where the process gas is injected to the reaction space. The plurality of second injecting pipes 256b are disposed along the surface of each first lower protruding portion 234b by an equal gap distance. In addition, at least two second slant injecting pipes 260b may be connected to one side of each second vertical injecting pipe 258b. The second process gas or the second process gas composition may be uniformly injected into the reaction space due to the plurality of second injecting pipes 256b having a uniform distribution.

FIG. 17 is a plan view showing a bottom surface of a lid of an apparatus for processing a substrate according to a second embodiment of the present invention.

In FIG. 17, the plurality of first injecting pipes 256a of each first gas injecting means 224a (of FIG. 12) and the plurality of second injecting pipes 256b of each second gas injecting means 224b (of FIG. 12) are uniformly disposed throughout the entire bottom surface of the lid 212a, and the process gas is supplied to the reaction space uniformly and radially. Since a blind spot where the process gas is not supplied does not exist in the process chamber 212, a thin film is uniformly formed on the substrate 120 or a thin film on the substrate 220 is uniformly patterned.

The first and second process gases or process gas compositions may include the same material as or the different material from each other. When the first and second process gases or the process gas compositions have the different material as each other, each first gas injecting means 224a formed in each second lower protruding portion 216b of each insulating plate 216 may supply the gas that is activated by the plasma and each second gas injecting means 224b formed in each upper protruding portion 234a and each first lower protruding portion 234b may supply the gas that is ionized to form the plasma. In another embodiment, each first gas injecting means 224a may supply the gas that is ionized and each second gas injecting means 224b may supply the gas that is activated.

Consequently, in a CCP type apparatus for processing a substrate, a standing wave effect is prevented by using a plurality of plasma source electrodes having a size smaller than a wavelength of an RF wave and a process gas is uniformly supplied to a reaction space by using a gas injecting means including a first gas injecting means in each of the plurality of plasma source electrodes and a second gas injecting means in each of a plurality of protruding portions. As a result, a thin film is uniformly deposited on a substrate or a thin film on a substrate is uniformly etched.

In an ICP type apparatus for processing a substrate, a process gas is uniformly supplied to a reaction space by using a gas injecting means including a first gas injecting means in each of a plurality of first protruding portions corresponding to an antenna as a plasma source electrode and a second gas injecting means in each of a plurality of second protruding portions as a plasma ground electrode. As a result, a thin film is uniformly deposited on a substrate or a thin film on a substrate is uniformly etched.

It will be apparent to those skilled in the art that various modifications and variations can be made in a laminating system and a laminating method using the laminating system of the present invention without departing from the spirit or scope of the invention. Thus, it is intended that the present invention cover the modifications and variations of this invention provided they come within the scope of the appended claims and their equivalents.

What is claimed is:

1. An apparatus for processing a substrate, comprising:
a process chamber providing a reaction space by a combination of a lid and a body;
a susceptor in the reaction space and having a substrate thereon;
a plurality of plasma source electrodes over the reaction space;
a plurality of first lower protruding portions under the lid; and
a plurality of first gas injecting means corresponding to the plurality of plasma source electrodes and a plurality of second gas injecting means alternately disposed with the plurality of first gas injecting means.

2. The apparatus according to claim 1, further comprising a plurality of insulating plates between the plurality of plasma source electrodes and the lid.

3. The apparatus according to claim 2, wherein the plurality of first gas injecting means are formed in the lid, the plurality of insulating plates and the plurality of plasma source electrodes, and the plurality of second gas injecting means are formed in the lid and the plurality of first lower protruding portions.

4. The apparatus according to claim 3, wherein each of the plurality of first gas injecting means comprises:
a sub gas supplying pipe supplying one of a process gas and a process gas composition;
a gas inlet pipe connected to the sub gas supplying pipe and formed in the lid and each of the plurality of insulating plates;
an inner connecting pipe connected to the gas inlet pipe; and
a plurality of injecting pipes branching out from the inner connecting pipes.

5. The apparatus according to claim 4, wherein the gas inlet pipe comprises:
an insulating pipe connected to the sub gas supplying pipe; and
a connecting pipe connected to the insulating pipe.

6. The apparatus according to claim 4, wherein each of the plurality of plasma source electrodes has a rectangular shape having a longer side and a shorter side, and the inner connecting pipe extends along two directions under the gas inlet pipe to be parallel to the longer side and perpendicular to the gas inlet pipe.

7. The apparatus according to claim 4, wherein the plurality of injecting pipes comprises:
a plurality of vertical injecting pipes connected to the inner connecting pipe; and
a plurality of slant injecting pipes branching out from each of the plurality of vertical injecting pipes.

8. The apparatus according to claim 7, wherein the plurality of slant injecting pipes are symmetrically disposed with respect to each of the plurality of vertical injecting pipes.

9. The apparatus according to claim 3, wherein each of the plurality of second gas injecting means comprises:
a sub gas supplying pipe supplying one of a process gas and a process gas composition;
a gas inlet pipe connected to the sub gas supplying pipe and formed in the lid and each of the plurality of first protruding portions;
an inner connecting pipe connected to the gas inlet pipe; and
a plurality of injecting pipes branching out from the inner connecting pipes.

10. The apparatus according to claim 2, wherein each of the plurality of first protruding portions includes an upper protruding portion vertically extending from the lid and a lower protruding portion expanding from the upper protruding portion, and wherein the upper protruding portion has the same thickness as each of the plurality of insulating plates.

11. The apparatus according to claim 1, wherein the plurality of first gas injecting means supplies one of a first process gas and a first process gas composition, and the plurality of second gas injecting means supplies one of a second process gas and a second process gas composition.

12. The apparatus according to claim 1, wherein each of the plurality of plasma source electrodes and the plurality of first protruding portions has one of a half circle and a half ellipse in a cross-sectional view.

13. The apparatus according to claim 1, further comprising:
a plurality of insulating plates sealing a plurality of open portions of the lid;
a plurality of second lower protruding portions under the plurality of insulating plates; and
a plurality of antennas over the plurality of insulating plates,
wherein the plurality of first gas injecting means are formed in the plurality of second lower protruding portions, and the plurality of second gas injecting means are formed in the plurality of first lower protruding portions.

14. The apparatus according to claim 13, wherein the lid includes a plurality of upper protruding portions alternately disposed with the plurality of insulating plates and a plurality of supporting portions extending from the plurality of upper protruding portions and supporting the plurality of insulating plates.

15. The apparatus according to claim 14, wherein the plurality of first gas injecting means are formed in the plurality of insulating plates, and the plurality of second gas injecting means are formed in the lid corresponding to the plurality of upper protruding portions and the plurality of first lower protruding portions.

16. The apparatus according to claim 14, wherein each of the plurality of first gas injecting means comprises:
a sub gas supplying pipe supplying one of a process gas and a process gas composition;
a gas inlet pipe connected to the sub gas supplying pipe and formed in the plurality of insulating plates;
an inner connecting pipe connected to the gas inlet pipe; and
a plurality of injecting pipes branching out from the inner connecting pipes.

17. The apparatus according to claim 16, wherein sub gas supplying pipe is inserted into an edge region of each of the plurality of insulating plates spaced apart from a central region of each of the plurality of insulating plates corresponding to each of the plurality of antennas.

18. The apparatus according to claim 16, wherein the gas inlet pipe comprises:
a first vertical inlet pipe connected to the sub gas supplying pipe;
a horizontal inlet pipe connected to the first vertical inlet pipe; and
a second vertical inlet pipe connected to the horizontal inlet pipe.

19. The apparatus according to claim 16, wherein the inner connecting pipe extends along two directions under the gas inlet pipe to be parallel to each of the plurality of open portions and perpendicular to the gas inlet pipe.

20. The apparatus according to claim 14, wherein each of the plurality of second gas injecting means comprises:
a sub gas supplying pipe supplying one of a process gas and a process gas composition;
a gas inlet pipe connected to the sub gas supplying pipe and formed in the lid corresponding to the plurality of upper protruding portions;
an inner connecting pipe connected to the gas inlet pipe; and
a plurality of injecting pipes branching out from the inner connecting pipes.

21. The apparatus according to claim 20, wherein the gas inlet pipe comprises:
an insulating pipe connected to the sub gas supplying pipe; and
a connecting pipe connected to the insulating pipe.

22. The apparatus according to claim 20, wherein the inner connecting pipe extends along two directions under the gas inlet pipe to be parallel to each of the plurality of open portions and perpendicular to the gas inlet pipe.

23. The apparatus according to claim 13, wherein each of the plurality of first lower protruding portions and the plurality of second protruding portions has one of a half circle and a half ellipse in a cross-sectional view.

24. The apparatus according to claim 13, wherein the plurality of antennas is used as a plasma source electrode for a radio frequency (RF) power and the lid is used as a plasma ground electrode.
